(19) United States
(12) Patent Application Publication
(10) Pub. No.: US 2005/0109281 A1
(43) Pub. Date: May 26, 2005

(54) Process for coating a substrate, and apparatus for carrying out the process

(76) Inventors: Holger Jurgensen, Aachen (DE); Michael Heuken, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/946,768

(22) Filed: Sep. 22, 2004

Related U.S. Application Data
(63) Continuation of application No. PCT/EP03/02860, filed on Mar. 19, 2003.

(30) Foreign Application Priority Data
Mar. 22, 2002 (DE) 102 12 923.1

(51) Int. Cl. C23C 16/00

(52) U.S. Cl. 118/725; 427/248.1

(57) ABSTRACT

The invention relates to a method and a device for coating at least one substrate with a thin layer in a processing chamber of a reactor. A solid or liquid starting material stored at least in a reservoir is guided into the processing chamber as a gas or an aerosol by means of a carrier gas, where it is condensed on the substrate. The solid or liquid starting material is maintained at a source temperature which is higher than the substrate temperature. In order to enable a targeted adjustment of the composition, sequence of layers and properties of the contact surface which determine the properties of the components, the carrier gas flows through the starting material and the supply of the gaseous starting material to the processing chamber is controlled by means of at least one valve and one mass flow regulator.

This application is a continuation of pending International Patent Application No. PCT/EP2003/002860 filed Mar. 19, 2003 which designates the United States and claims priority of pending German Patent Application No. 102 12 923.1 filed Mar. 22, 2002.

### FIELD OF THE INVENTION

The invention relates to a process for coating at least one substrate with a thin layer in a process chamber of a reactor, in which at least one solid or liquid starting material, which is stored in a storage vessel, is introduced as a gas or aerosol into the process chamber by means of a carrier gas, where it condenses on a substrate, the solid or liquid starting material being held at a source temperature which is higher than the substrate temperature. Furthermore, the invention relates to an apparatus, in particular for carrying out this process, having a reactor housing and a process chamber, which is disposed therein and in which are located a substrate holder whose temperature can be controlled and a gas inlet member whose temperature can be controlled, having gas lines, whose temperature can be controlled, leading from a plurality of vessels whose temperature can be controlled, each for receiving a solid or liquid starting material, to the gas inlet member, for a carrier gas and the respective starting material which has been converted into gas form. The starting material is stored at a regulated pressure in the vessels. The coating is carried out in the process chamber, likewise at a regulated pressure.

WO 01/61077 A2 describes an apparatus of this type. In that apparatus, a coolable substrate holder, opposite which there is a heatable gas inlet member in the form of a shower head, is located in a process chamber of a reactor. Gas powers, through which a carrier gas and gaseous starting materials dissolved in the respective carrier gas are fed to the process chamber, open out separately from one another into the gas inlet member. The gaseous starting materials originate from vessels which are heated to a source temperature. Gaseous or liquid starting materials are located in these vessels. The liquid or solid starting material evaporates through the closable vessel openings. This vapor is transported by the carrier gas.

This document WO 01/61071 A1 cites further documents, which likewise deal with a condensation coating process of the generic type, for example U.S. Pat. No. 5,554,220. The latter document discloses an OVPD process. This process is intended to deposit layers formed from optical, nonlinear, organic salts. These salts are stored in a vessel (crucible) which is located in a hot zone of the reactor. The organic salt evaporates on account of the source temperature prevailing there. The solid starting material which has been converted into gas form is transported onward into a deposition zone, by means of a carrier gas stream flowing over the vessel, with a substrate disposed on a substrate holder in the deposition zone. Since the substrate temperature is lower than the source temperature, the gaseous starting material condenses on the substrate surface to form a thin film. This method and the apparatuses described there can be used to produce the base materials, namely layers, for organic light-emitting diodes OLEDs from small molecules.

In the evaporation process, the layer thickness to be achieved is determined by the deposition time. The deposition rate is determined by the temperature of the evaporator vessel. If a plurality of sources, i.e. a plurality of vessels or crucibles, is used, cross-contamination may occur between the various source substances. Therefore, each source has to be disposed in a separate process chamber. Furthermore, an undesirable distribution of materials with a high vapor pressure throughout the entire deposition system occurs. This leads to uncontrolled entrainment into subsequent layers of the structure or into the next process.

OLEDs with a high luminous power, low operating voltages and a long service life require a sequence of a large number of doped and undoped layers. These layers have to be deposited in succession in a process. These layers include electron conductors and hole conductors, barrier layers and active light-emitting, light-conducting or light-reflecting layers. These layers should preferably be produced in such a way that the composition and therefore their properties change in the deposition direction. The layer properties, i.e. the layer composition or the dopant content, should be able to change both abruptly and at a constant, controlled rate. The former option is required for sharply defined interfaces between the layers.

The invention is based on the object of overcoming the drawbacks explained above and providing a process which allows controlled setting of composition, layer sequence and properties of the interface which determine the properties of the components.

The object is achieved by the invention given in the claims.

Claim 1 deals with a process in which the carrier gas flows through the starting material and the supply of the gaseous starting material to the process chamber is controlled by means of at least one valve and a mass flow controller. The valve is preferably a switching valve which is disposed between the vessel and the gas inlet member. The mass flow controller may be disposed upstream of the vessel. To keep the evaporation rate constant, the vessel is thermostated. The gas feed line to the vessel is preferably also thermostated, so that the gas flowing in the vessel is at the same temperature as the solid or liquid starting material. To control the gas pressure inside the vessel, it is possible for a pressure-control member, by means of which the pressure in the vessel is held at a predefined value, to be located downstream of the vessel in the gas line. By means of the valve, the gas flow streaming out of the vessel, comprising the carrier gas and the gaseous starting material dissolved therein, can be passed either into the process chamber or into an exhaust. This vent/run switching allows accurate presetting of the gas concentration and allows the starting materials to be switched on suddenly. In a refinement of the invention, it is provided that at least two different vessels contain starting materials different from one another and a carrier gas flows through them individually, and the supply of the respective gaseous starting materials to the process chamber is controlled by means of valves and mass flow controllers. In this case, a valve and a mass flow controller are associated with each vessel. Furthermore, it is possible to provide for the supply of at least one of the at least two starting materials, dissolved in each case in a carrier gas, to be altered by varying the controlled mass flow during the deposition process. Furthermore, there is provision for the mass flow to be switched on or off. However, the mass flow may also increase or decrease at a constant rate. The starting materials used are preferably organic molecules. The deposited layer can be processed further to form an OLED. It is preferable for a multiplicity of layers comprising one or more starting materials to be deposited in succession. The layers of these layer sequences may consist of different materials. The apparatus according to the invention is distinguished by the fact that the gas streams which are conducted to the gas inlet member can be passed into the process chamber in a manner which is controllable over the course of time by means of valves and gas mass flow controllers. For this purpose, there is provision in particular for medium to flow through each of the vessels from the bottom upward. The gaseous or liquid starting material may therefore be located on a porous intermediate wall of the vessel, through which the carrier gas, the temperature of which has been controlled to the temperature of the starting material, flows. The mass flow controllers are preferably disposed upstream of the vessel. A switching valve is disposed downstream of the vessel. A pressure regulator may likewise be disposed downstream of the vessel and is located between vessel and the switching valve.

The gaseous starting materials for producing the component structures are transported in a gas stream, e.g. nitrogen, argon or helium.

The deposition rate, the composition and the quantity of dopant incorporated into the layer are determined by the concentration of the respective starting substances in the gas stream. The respective concentration in the gas stream is set by means of a plurality of independent mass flow controllers. Dilution lines are also provided, opening out into the feed line to the gas inlet member downstream of the switching valve. By changing the source temperature, it is possible to vary the vapor pressure of the starting materials in the respective vessels independently of one another, in order thereby to significantly increase or reduce the concentration in the gas flow. The respective source vessel is constructed in such a way that the composition of the gas stream changes reproducibly and virtually linearly with the carrier gas flow. The lines from the sources to the reactor are constructed in such a way that the gas compositions which are set are retained. The temperature of the gas lines is in particular controlled in such a manner that the vapor pressure of the gaseous starting material in the carrier gas is lower than the saturation vapor pressure, so that no condensation can occur. These considerations also apply to the temperature of the gas inlet member. On account of the fact that the sources and the lines are separated, there is no cross-contamination. The pressures in the lines and in the vessels are regulated using the abovementioned pressure regulator. The valves allow the source to be switched on and off abruptly and reproducibly. These valves are as far as possible located in the vicinity of the reactor. Since all the sources are physically separated from one another, there is no cross-contamination between the sources. The deposition of a layer sequence which comprises a plurality of qualitatively different layers can be realized in one process chamber, specifically in steps which immediately follow one another. The gas streams have no influence on one another, since the greatly diluted source flows are combined only just upstream of the process chamber. The gas inlet member of the reactor and the gas path from the gas inlet member to the substrate are configured in such a way that the gas compositions which are set do not change in a non-reproducible manner. The layer thicknesses are therefore substantially defined only by the switching times. The structure of the process chamber and the peripherals in accordance with the invention, i.e. the positioning of the valves of the vessels and the mass flow regulators, allows the composition of the gas phase and therefore the layer composition to be changed very quickly. The vent/run switching described above allows accurate presetting of the gas concentration. It is preferable for there to be no unpurged empty spaces throughout the entire deposition system, so that there is no undesirable mixing of the gases. For these reasons, the properties of the interfaces between the individual deposited layers can be set accurately. In pauses between growth phases, the surfaces can be purged with an inert gas. The pause times can be selected as desired, in particular on account of the vent/run switching. Minimal pause times in the region of a few seconds fractions are possible. Switching times for the position or pauses ranging from a few fractions of a second to several minutes can be set. The process parameters in the pauses between growth phases can as far as possible be set freely. For example, it is possible to preset the gas flow, the temperature. The process according to the invention is distinguished by the fact that the growth of the layers can not only be commenced or terminated gradually, but rather can also be switched on or off abruptly. This leads to an accurate control of the interfaces between the individual layers deposited on one another. The layers may have a thickness of just a few nanometers. It is even possible for subatomic films to be deposited between the individual layers in order to influence the interfaces. The surface charges can be saturated by means of these subatomic films. This leads to a desired band bending. Metals or polymers can be deposited in order to influence the interfaces and in particular the interfacial charges. However, it is also possible for the interfaces to be influenced simply by interrupting the growth. For this purpose, the deposition is switched off abruptly. This is followed by waiting for a certain time. No growth takes place during this time. The surface may change electronically during this time. After the waiting time, the layer growth can be recommenced abruptly or gradually. According to the invention, the starting materials used are solids or liquids. In this context, it is possible to use starting materials which can be evaporated. However, it is also possible to use starting materials whose vaporization temperature is higher than the decomposition temperature. Materials of this type cannot be vaporized, since they are chemically decomposed before they can be vaporized. These materials can be transported in the form of an aerosol, i.e. a mist.

### BRIEF DESCRIPTION OF DRAWINGS

Exemplary embodiments of the invention are explained on the basis of appended drawings, in which:

FIG. 1 shows a highly diagrammatic structure of an apparatus for carrying out the process, with a reactor which includes a process chamber and two vessels for the starting materials,

FIG. 2a shows the time curve of the concentration of a dopant passed into the process chamber,

FIG. 2b shows the associated curve of the concentration of a layer-forming starting material (A) introduced into the process chamber,

FIG. 2c shows the resultant dopant profile in the layer as a function of the layer thickness,

FIG. 3a shows the time curve of the concentration of a first starting material (A) passed into the process chamber,

FIG. 3b corresponding to FIG. 3a, shows the time curve of the concentration of a second starting material (B) passed into the process chamber,

FIG. 3c corresponding to FIGS. 3a and 3b, shows the layer composition as a depth profile,

FIG. 4 shows a highly diagrammatic view of a further exemplary embodiment of a coating apparatus,

FIG. 5 shows the outline of a circular gas outlet member 4,

FIG. 6 shows the outline of a rectangular gas outlet member in the form of a square,

FIG. 7 shows the outline of a rectangular gas outlet member in the form of a narrow strip, and

FIG. 8 shows a further exemplary embodiment in accordance with FIG. 4.

### DETAILED DESCRIPTION OF DRAWINGS

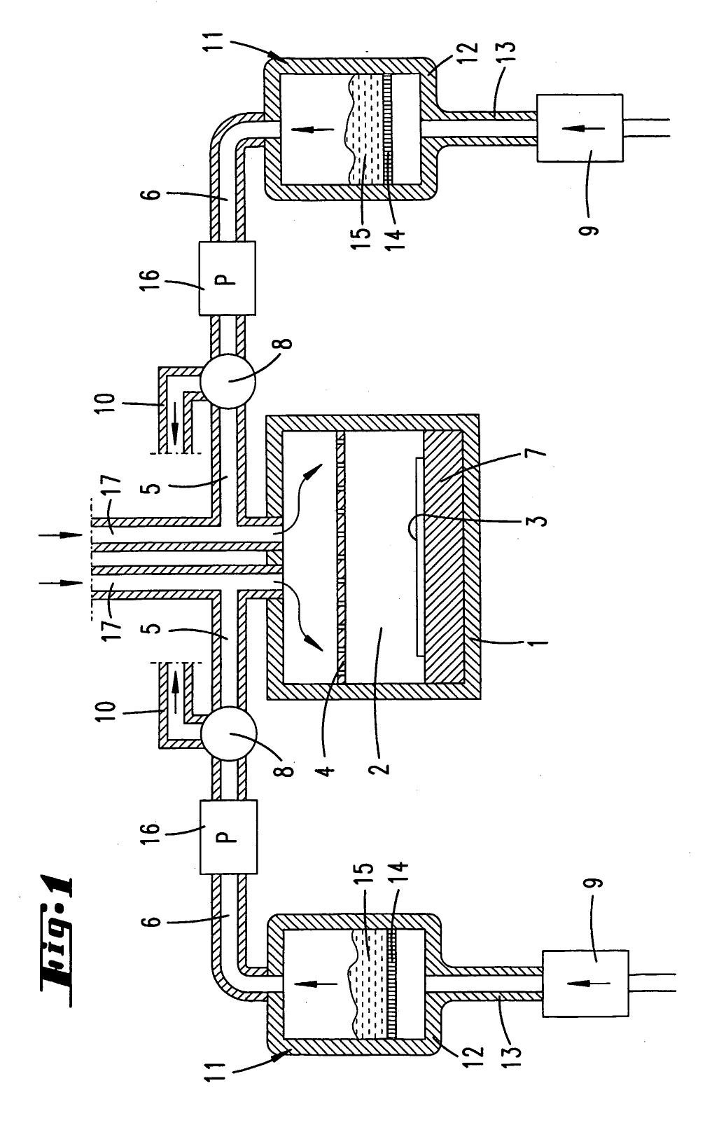

The apparatus illustrated in FIG. 1 comprises a reactor 1, which has a housing whose temperature can be controlled. The heating and the gas discharge line, as well as further structural features of this reactor 1 which are known per se, are not shown in the drawing for the sake of clarity. The base of the process chamber 2 located in the reactor is formed by a substrate holder 7, the temperature of which can be controlled. The substrate holder 7 is generally cooled, so that the gaseous starting materials flowing into the process chamber 2 through the gas inlet member 4 condense on the substrate 3 located on the substrate holder 7, so as to form a thin layer.

The gas inlet member 4 may be in the form of a shower head. A gas-mixing chamber, into which a plurality of temperature-controlled gas lines 5 open out, is located above the gas inlet member 4. Two temperature-controlled lines 5 are illustrated in the exemplary embodiment. The temperature of the lines 5 and of the gas inlet member 4 is higher than the substrate temperature, and at a level which is such that the gaseous starting material does not condense, does not change chemically and in particular does not decompose within the lines.

The gaseous starting materials are provided in gas sources. These gas sources comprise a vessel 11, which has a wall 12 whose temperature can be controlled. The wall 12 is heated to a source temperature which is higher than the substrate temperature. A temperature-controlled feed line 13 opens out into the base of the vessel 11. The line is preferably held at the same temperature as the vessel wall 12. The line 13 is fed with a carrier gas, the flow of which is set by a mass flow controller 9. Examples of suitable carrier gases include nitrogen, argon and helium. This carrier gas flows through a porous intermediate wall 14. The solid and if appropriate also liquid starting material is located on the porous intermediate wall 14. The starting material consists of small organic molecules, as mentioned, for example, in U.S. Pat. No. 5,554,220. The carrier gas flows through the liquid or solid starting material 15. The carrier gas stream flowing out at the vessel opening at the top is laden, preferably saturated, with the gaseous starting material. The temperature-controlled line 6 opens out into a pressure regulator 16, by means of which the vessel pressure is regulated. A temperature-controlled switching valve 8, by means of which the gas flow can be passed either into the gas inlet member 4 or into a vent line 10, is located downstream of the pressure regulator 16. Just upstream of where the gas line 5 opens out into the gas inlet member 4, carrier gas lines 17 open out into the gas line 5, in order to allow optional additional dilution or in order to realize bypass operation. By way of example, a gas stream may be passed through the line 17 only when the valve 8 switches the gas stream coming out of the vessel 15 into the vent line 10. It is preferable for the gas streams flowing through the line 17 and the vent line 19 to be equal in magnitude.

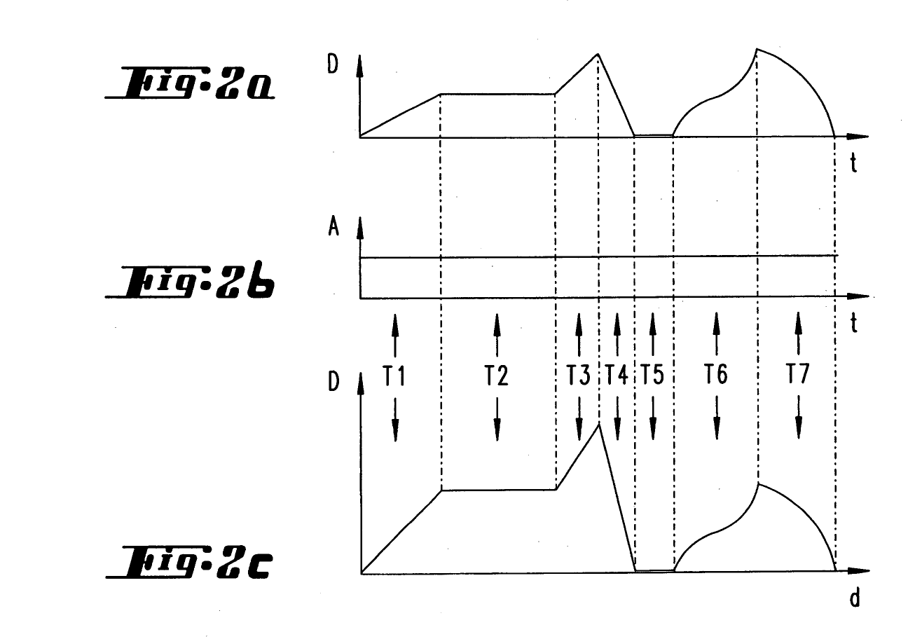

FIGS. 2a to 2c show the process according to the invention on the basis of the example of the production of a dopant profile. By suitably varying the carrier gas stream passed into the vessel by the mass flow controller 9, it is possible to set the dopant gas concentration, which is plotted in FIG. 2a, within the gas phase above the substrate. During phase T1, the dopant concentration increases linearly over the course of time. During phase T2, it is kept constant, during phase T3 the dopant concentration rises further at a constant rate as a result of a suitable increase in the gas flow through the vessel 15. In phase T4, the dopant concentration is linearly reduced to zero by a constant reduction in the gas stream. The valve 8 is closed during phase T5. In phase T6, the gas stream is changed in nonlinear fashion over the course of time. In phase T7, the gas stream is reduced, likewise in nonlinear fashion over the course of time.

The flow through the vessel containing the layer material illustrated in FIG. 2b remains constant. Accordingly, the gas concentration of the associated starting material in the gas phase above the substrate is constant.

The layer growth takes place at a constant growth rate. Only the incorporation of dopant varies over the course of time. This results in the dopant profile illustrated in FIG. 2c.

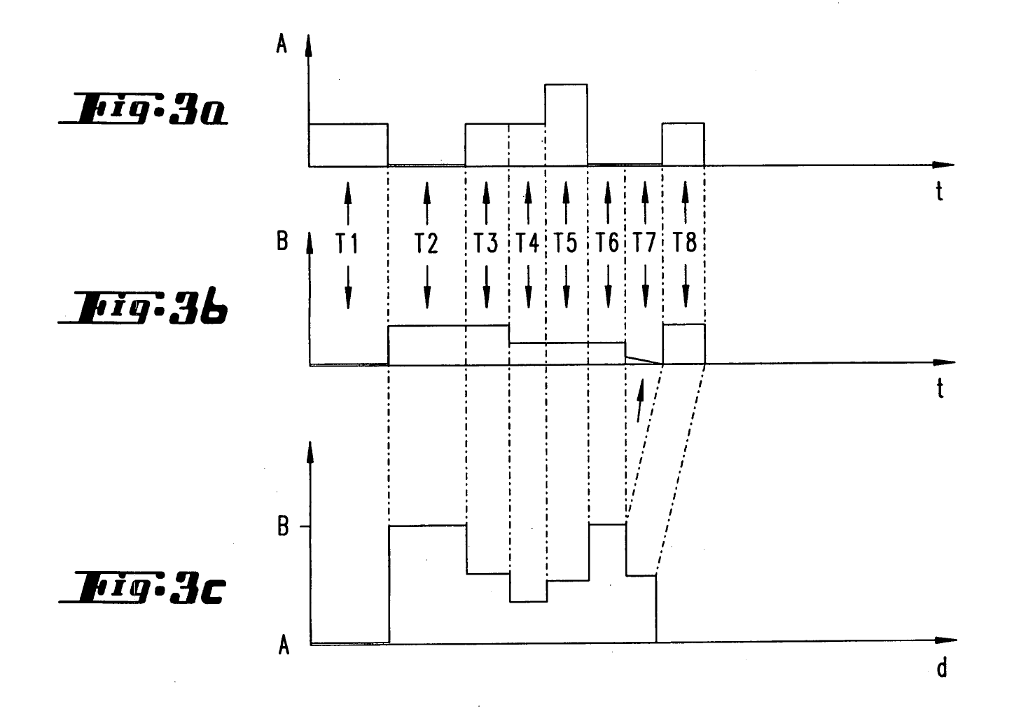

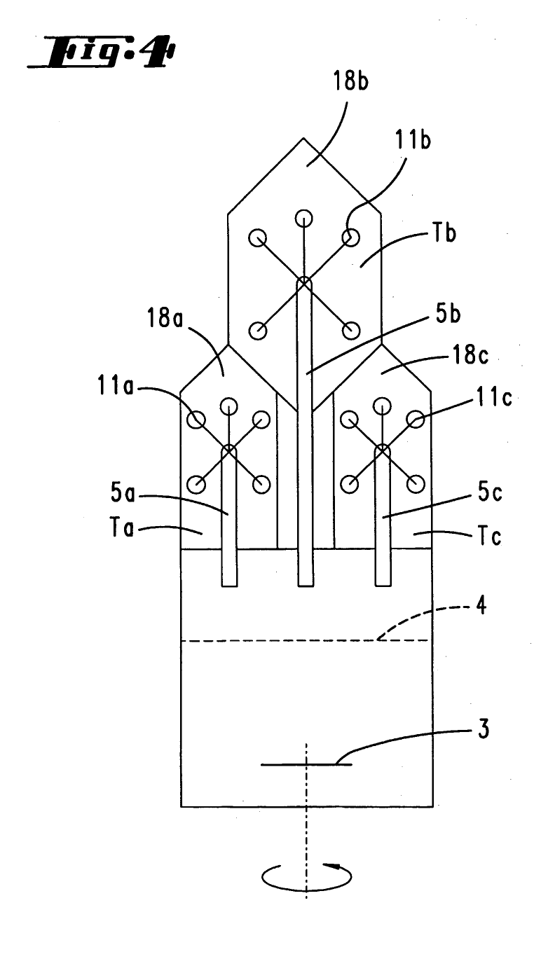

FIGS. 3a to 3c show, by way of example, how the layer composition can be varied over the course of time. Two starting materials A and B can be introduced into the process chamber 3 independently of one another. Each starting material A, B is located in a separate vessel 11. The gas streams passing through the vessels 11 can be set individually. The gas stream flowing through the vessel 11 in which the substance A is located is illustrated in FIG. 3a. The concentration of this gaseous starting material in the process chamber varies accordingly.

FIG. 3b illustrates the gas flow flowing through the vessel 11 containing the starting material B over the course of time. The concentration of the gaseous component B in the gas phase above the substrate 3 changes accordingly with the gas flow.

In phase T1, the switching valve 8 associated with material B is closed, and only starting material A is passed into the process chamber. As can be seen from FIG. 3c, the associated layer contains only component A. In phase T2, the switching valve associated with component A is switched to vent, i.e. closed, and only component B is passed into the process chamber. Accordingly, the associated layer comprises only material B. In phase T3, material A is switched on by switching the valve 8. The associated layer comprises both materials. In phase T4, the flow through the vessel containing material B is reduced. More material A than material B is deposited. In phase T5, the gas flow through the vessel containing component A is increased. The layer composition changes accordingly. In phase T6, the valve belonging to component A is switched to vent. Accordingly, the layer comprises only component B. In phase T7, both valves 8 are switched to vent. No layer growth takes place. During this phase, the process chamber can be purged with an inert gas. In phase T8, both valves 8 are switched to run. A layer comprising components A and B is deposited.

Of course, it is also possible for the carrier gases flowing through the vessels containing components A or B to be varied over the course of time, as shown in FIG. 2a. In this case, the composition of the layer changes continuously. This makes it possible to produce ramp profiles.

Furthermore, it is also possible to vary the composition of the gas phase in the process chamber 2 immediately above the substrate 3 by varying the temperature inside the vessels 11. However, faster variation can be achieved by varying the gas flow by means of the mass flow controllers 9. Furthermore, a variation can also be achieved by changing the pressure. For this purpose, the preset value for the pressure-regulating member 16 is changed.

The process according to the invention and the apparatus according to the invention can be used to influence the interfaces between the individual layers deposited on one another. In particular, there is provision for a subatomic film, for example of a metal or a polymer, to be deposited on the surface of one of the layers. Surface charges can be saturated by means of an interlayer of this type or a similar interlayer. This leads to controlled band bending. However, there is also provision for the interface properties to be influenced simply by interrupting the growth process. The typical layer thickness of a deposited layer is between 10 and 15 nanometers. The overall structure, comprising a multiplicity of layers, has a total thickness of from 100 to 150 nanometers. In addition to the fields of application described above, the process according to the invention can also be used to produce white light emitters for illumination technology.

According to the invention, it is also possible for the starting materials used to be materials which cannot be vaporized, on account of their low decomposition temperature. Starting materials of this nature which cannot be vaporized, having a vaporization temperature which is higher than the decomposition temperature, are transported as aerosols.

The diagrammatic illustration presented in FIG. 4 shows an exemplary embodiment in which a plurality of thermostated chambers 18a, 18b and 18c are provided. The individual thermostated chambers 18a, 18b and 18c are held at different temperatures Ta, Tb, Tc. In each case a multiplicity of vessels 11a, 11b, 11c, in which solid or liquid starting materials are located, are located inside the chambers 18a, 18b, 18c, and these starting materials are fed via a gas inlet member 4, in the manner described above, to the process chamber, where a rotationally driven substrate 3 is located.

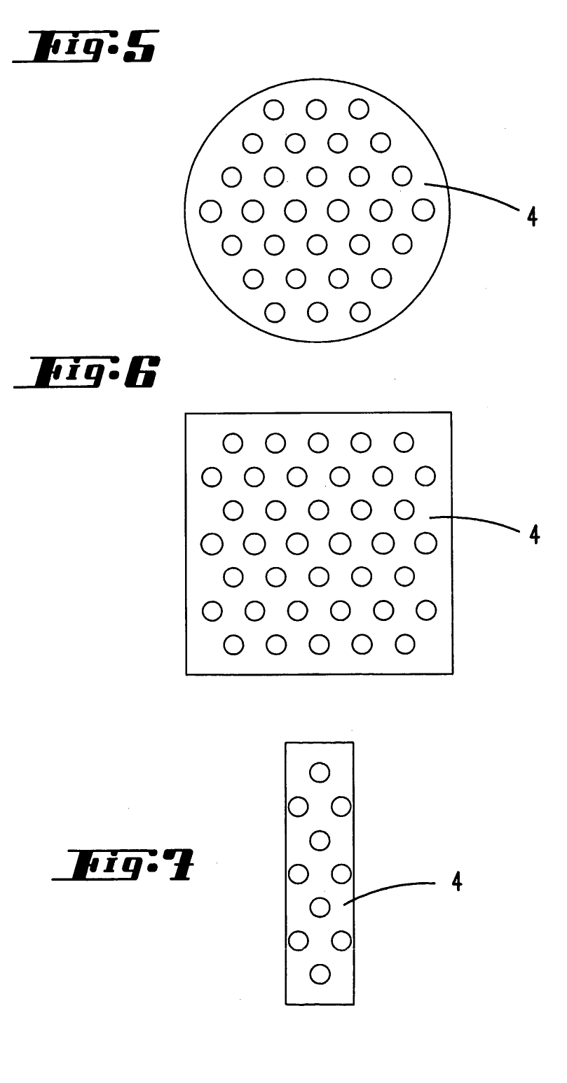

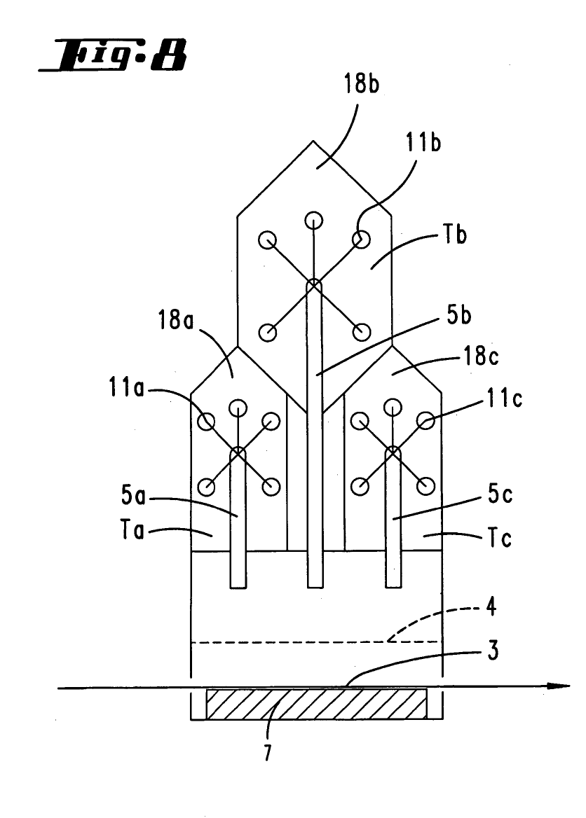

The outline shape of the gas outlet surface of the gas inlet member 4 may take various shapes. As illustrated in FIG. 5, the shape may be in the form of a circular disk. As illustrated in FIG. 6, the outline shape of the gas outlet surface of the gas inlet member 6 may be square. This shape, and also the narrow, quasi-linear shape of the gas outlet surface illustrated in FIG. 7, is used in particular for apparatuses and processes in which an endless substrate is coated. An apparatus of this type is diagrammatically depicted in FIG. 8. In this case, the endless, flexible substrate 3 enters the process chamber on one side and slides over a substrate holder 7, the temperature of which can be controlled. The flexible substrate 3 leaves the process chamber again on the other side.

It is possible to laterally pattern the layer through masks. It is preferable for a multiplicity of layers to be deposited within the process chamber. In addition, a protective, insulating or antireflection coating can be applied to the layer sequence.

All the features disclosed are (inherently) pertinent to the invention. The content of disclosure of the associated/appended priority documents (copy of the prior application) is hereby incorporated in its entirety in the disclosure of the application, partly with a view to incorporating features of these documents in claims of the present application.

1. Process for coating at least one substrate with a thin layer in a process chamber of a reactor, in which a solid or liquid starting material, which is stored at least in one storage vessel, is introduced as a gas or aerosol into the process chamber by means of a carrier gas, where it condenses on the substrate, the solid or liquid starting material being held at a source temperature which is higher than the substrate temperature, and the carrier gas flowing through the starting material, the supply of the gaseous starting material to the process chamber being controlled by means of at least one valve, characterized in that the pressure in the storage vessel is regulated by means of a pressure regulator disposed downstream of the storage vessel, and the gas stream regulated by a mass flow controller disposed upstream of the storage vessel can be switched into a vent line by means of a switching valve disposed downstream of the pressure regulator.

2. Process according to claim 1, characterized in that at least two different vessels contain different starting materials and a carrier gas flows through them individually, and the supply of the respective gaseous starting material to the process chamber is controlled by means of in each case at least one valve and in each case at least one mass flow controller.

3. Process according to claim 1, characterized in that the supply of at least one of the starting materials, dissolved in each case in at least one carrier gas, is altered by varying the controlled gas flow during the deposition process.

4. Process according to claim 1, characterized in that the mass flow is switched on or off suddenly.

5. Process according to claim 1, characterized in that the mass flow increases or decreases at a constant rate.

6. Process according to claim 1, characterized in that the starting material or starting materials is/are organic molecules, and the deposited layer is processed further to form an OLED.

7. Process according to claim 1, characterized in that a multiplicity of layers comprising one or more starting materials are deposited in succession.

8. Process according to claim 1, characterized in that the layer sequence is realized in coating steps which immediately follow one another in the same process chamber, by simply changing the gas composition.

9. Process according to claim 1, characterized in that n- and p-conducting layers are deposited.

10. Process according to claim 1, characterized in that undoped interlayers are deposited between the doped layers.

11. Process according to claim 1, characterized in that the concentration/composition layer thickness profile corresponds to the temporal profile of the carrier gas flows passing through the vessels.

12. Process according to claim 1, characterized in that solar cells, sensors or transistors are produced from the deposited layers/layer sequences.

13. Process according to claim 1, characterized in that deposition of an organic layer is locally delimited on the substrate by varying the gas routing, the pressure and the temperature.

14. Process according to claim 1, characterized in that the deposition is realized on endless, flexible substrates.

15. Process according to claim 1, characterized by lateral patterning of the layer growth through masks.

16. Process according to claim 1, characterized in that the layers/layer sequences are coated with a protective, insulating or antireflection coating or with a metal in a subsequent process carried out in the same process chamber.

17. Apparatus for carrying out the process according to claim 1, having a reactor housing and a process chamber, which is disposed therein and in which are located a substrate holder whose temperature can be controlled and a gas inlet member whose temperature can be controlled, having gas lines, whose temperature can be controlled, leading from a plurality of vessels whose temperature can be controlled, each for receiving a solid or liquid starting material, to the gas inlet member, for a carrier gas and the respective starting material which has been converted into gas form, in which apparatus the gas streams of the gaseous starting materials dissolved in the carrier gas can each individually be passed into the process chamber in a manner which can be controlled over the course of time by means of valves, characterized by a pressure regulator disposed downstream of the storage vessel for regulating the pressure in the storage vessel and a switching valve disposed downstream of the pressure regulator for switching the gas stream regulated by a mass flow controller disposed upstream of the storage vessel into a vent line.

18. Apparatus according to claim 1, characterized by vessels through which medium can flow from the bottom upward.

19. Apparatus according to claim 1, characterized by mass flow controllers connected upstream of the vessels.

20. Apparatus according to claim 1, characterized by switching valves which are connected downstream of the vessels and by means of which the gaseous starting materials and the carrier gas carrying them can be switched either into the process chamber or into a vent line.

21. Apparatus according to claim 1, characterized by a pressure-regulating member disposed between the valve and the vessel.
